(19) United States
(12) Patent Application Publication
(10) Pub. No.: US 2013/0293858 A1
(43) Pub. Date: Nov. 7, 2013

(54) ANISOTROPIC PHASE SHIFTING MASK

(71) Applicants: Burn Jeng Lin, Hsinchu City (TW); Hoi-Tou Ng, Hsinchu City (TW); Ken-Hsien Hsieh, Taipei City (TW); Shou-Yen Chou, Ji-An Shiang (TW)

(72) Inventors: Burn Jeng Lin, Hsinchu City (TW); Hoi-Tou Ng, Hsinchu City (TW); Ken-Hsien Hsieh, Taipei City (TW); Shou-Yen Chou, Ji-An Shiang (TW)

(73) Assignee: TAIWAN SEMICONDUCTOR MANUFACTURING COMPANY, LTD., Hsin-Chu (TW)

(21) Appl. No.: 13/464,325

(22) Filed: May 4, 2012

(51) Int. Cl. G03F 1/26; G03F 7/20; G03B 27/42

(52) U.S. Cl. 355/53; 430/5; 355/77

(57) ABSTRACT

The present disclosure provides a photomask. The photomask includes a substrate. The photomask also includes a plurality of patterns disposed on the substrate. Each pattern is phase shifted from adjacent patterns by different amounts in different directions. The present disclosure also includes a method for performing a lithography process. The method includes forming a patternable layer over a wafer. The method also includes performing an exposure process to the patternable layer. The exposure process is performed at least in part through a phase shifted photomask. The phase shifted photomask contains a plurality of patterns that are each phase shifted from adjacent patterns by different amounts in different directions. The method includes patterning the patternable layer.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

As semiconductor fabrication technology progresses from one generation to the next, it has become increasingly more difficult for conventional lithography processes to achieve good resolution for the shrinking IC patterns. For example, minimum pitch and line end spacing may become performance bottlenecks for conventional lithography processes.

Therefore, although existing lithography processes have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a simplified top view of a wafer.

FIG. 2 illustrates a simplified top view of a photomask according to an embodiment of the present disclosure.

FIG. 3 illustrates a simplified cross-sectional view of a portion of the photomask of FIG. 2.

FIG. 4 illustrates a simplified top view of an aperture that can be used in conjunction with the photomask of FIG. 2 to perform a lithography process according to various aspects of the present disclosure.

FIG. 5 illustrates a simplified diagrammatic view of a lithography system according to various aspects of the present disclosure.

FIG. 6 illustrates a simplified top view of an alternative embodiment of an aperture that can be used in conjunction with the photomask of FIG. 2 to perform a lithography process according to various aspects of the present disclosure.

FIG. 7 illustrates a simplified top view of a photomask according to an alternative embodiment of the present disclosure.

FIG. 8 illustrates a simplified top view of a photomask according to yet another alternative embodiment of the present disclosure.

FIG. 9 illustrates a flowchart of a method of performing a lithography process according to various aspects of the present disclosure.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

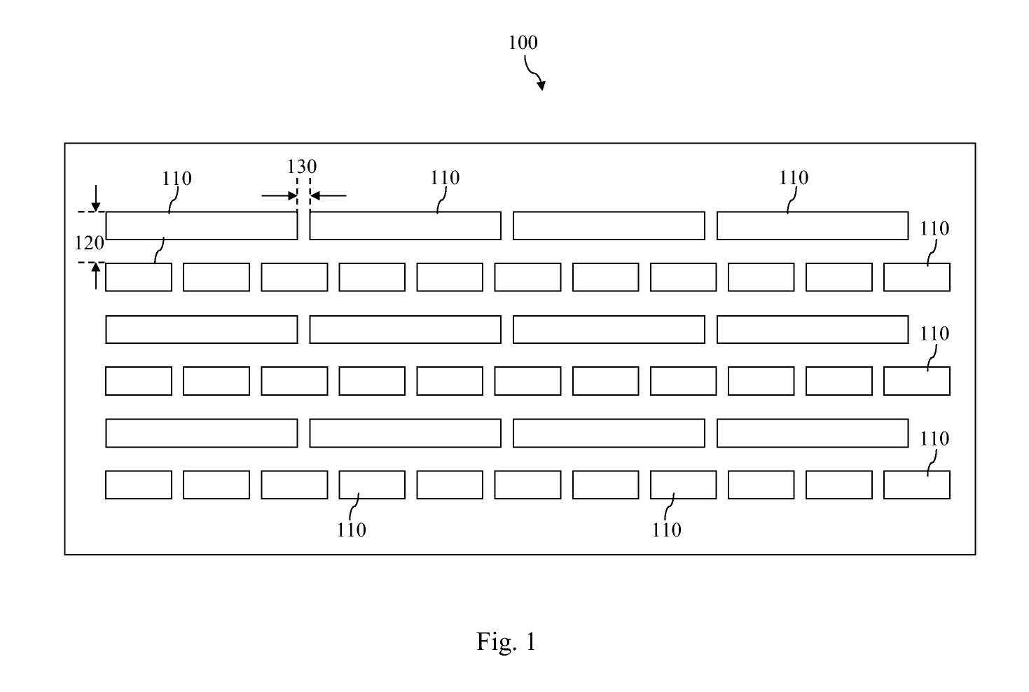

As semiconductor feature sizes continue to shrink, it has become increasingly more difficult for lithography processes to achieve the necessary resolution. For example, referring to FIG. 1, which shows a simplified diagrammatic fragmentary view of a portion of a wafer 100. The wafer 100 contains a plurality of patterns (or features) 110. A pitch is defined as a sum of a width of a pattern 110 and the separation between adjacent patterns 110. Line end spacing is defined as the distance between two adjacent patterns 110. An example pitch 120 and an example line end spacing 130 are illustrated in FIG. 1.

As the scaling down process continues, conventional lithography processes may not be able to achieve satisfactory resolution for the patterns 110. For example, the minimum pitch 120 and/or the line end spacing 130 may not be satisfactorily imaged for conventional lithography processes. For example, some conventional lithography processes may yield an acceptable minimum pitch, but may fail to produce an acceptable line end spacing. Some other conventional lithography processes may yield an acceptable line end spacing, but may fail to produce an acceptable minimum pitch.

According to the various aspects of the present disclosure, a method and apparatus for performing an improved lithography process is disclosed. The improved lithography process of the present disclosure is capable of achieving both good minimum pitch performance and good line end spacing performance.

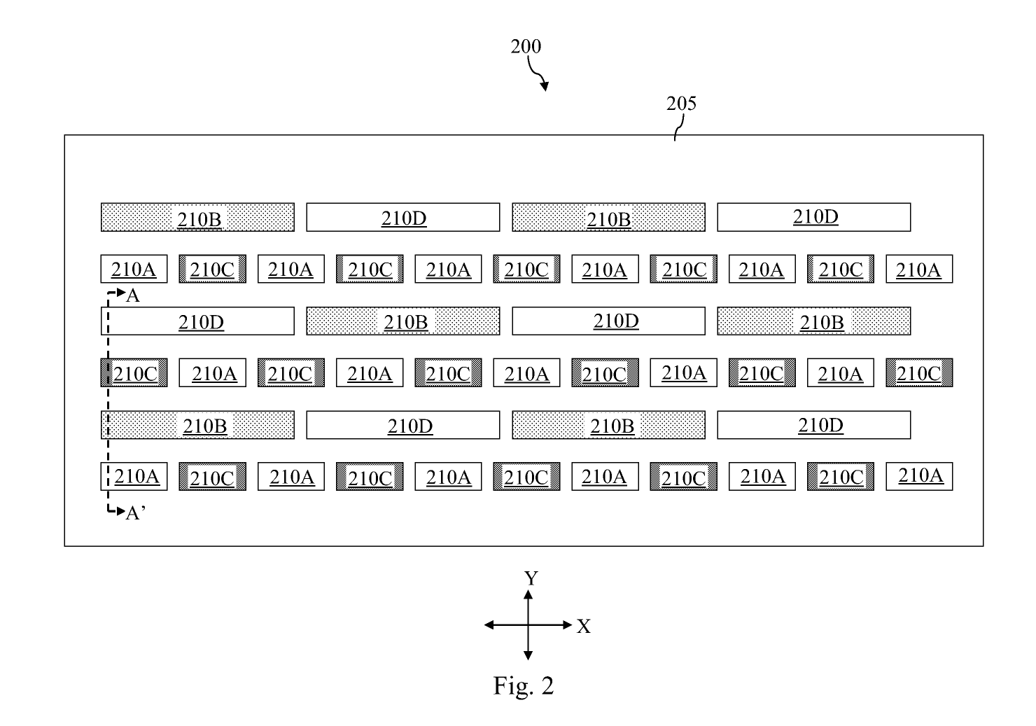

FIG. 2 shows a simplified diagrammatic fragmentary top view (or a plan view) of a portion of a photomask 200 (also referred to as a reticle) according to an embodiment of the present disclosure. The top view is defined by an X-direction (or X-axis) and a Y-direction (or Y-axis) perpendicular to the X-direction. In certain embodiments, the X-direction may be referred to as a horizontal direction, while the Y-direction may be referred to as a vertical direction for ease of reference. The photomask 200 includes a substrate 205. In some embodiments, the substrate 205 may include a fused quartz material. The substrate 205 is transparent so that light beams can pass through.

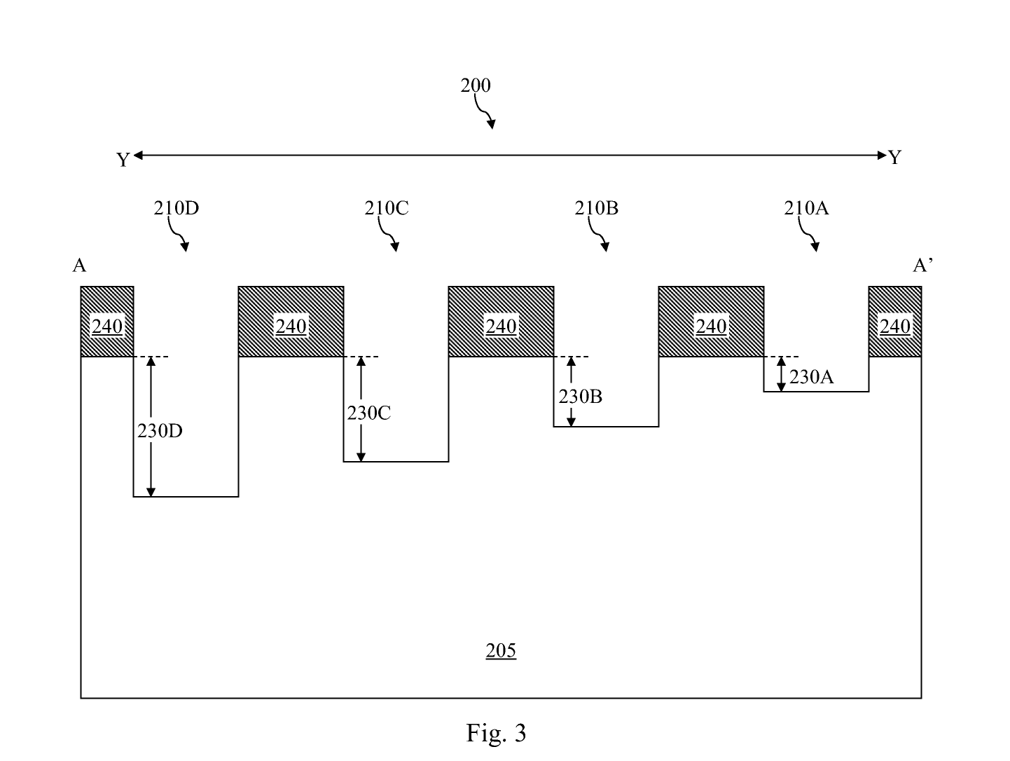

The photomask 200 also includes a plurality of patterns (or features) 210 disposed on or in the substrate 205. In some embodiments, the patterns 210 correspond to semiconductor device components of an Integrated Circuit (IC). In other words, the patterns 210 may be used in a lithography process to define images of semiconductor device components on a wafer. The patterns 210 may correspond to gate lines or metal lines, for example. In some embodiments, the patterns 210 include trenches or openings formed in the substrate 205. As an example, a fragmentary cross-sectional view of the photomask 200 is taken from point A to point A′ and shown in FIG. 3, which will be discussed in more detail below.

Still referring to FIG. 2, the patterns 210 are divided into a plurality of subsets. For example, in the illustrated embodiment, the patterns 210 are divided into four subsets containing patterns 210A, 210B, 210C, and 210D, respectively. The patterns 210 in each subset is phase shifted from patterns in other subsets. For example, the subset of patterns 210A is at a 0 phase, the subset of patterns 210B is at a π/2 phase, the subset of patterns 210C is at a π phase, and the subset of patterns 210D is at a 3π/2 phase, where π is 180 degrees. Thus, a certain phase shift exists between any two patterns 210 from different subsets.

According to various aspects of the present disclosure, each pattern 210 is shifted from adjacent patterns by different amounts in different directions, but a magnitude of an amount of phase shift between adjacent patterns is approximately the same in any given direction. For instance, each pattern is phase shifted from its adjacent features in the X-direction by a first amount, and each pattern is phase shifted from its adjacent features in the Y-direction by a second amount that is different from the first amount.

Using the embodiment shown in FIG. 2 as an example to illustrate the above concept, the pattern 210A is adjacent to the pattern 210C in the X-direction. A magnitude of the amount of phase shift between the patterns 210A and 210C is π, since the pattern 210A is at a 0 phase, and the pattern 210C is at a π phase. Meanwhile, the pattern 210A is adjacent to the patterns 210B or 210D in the Y-direction. A magnitude of the amount of phase shift between the patterns 210A and 210B is π/2, since the pattern 210A is at a 0 phase, and the pattern 210B is at a π/2 phase. A magnitude of the amount of phase shift between the patterns 210A and 210D is also π/2, since the pattern 210A is at a 0 phase, and the pattern 210D is at a 3π/2 phase. Therefore, in the embodiment illustrated in FIG. 2, the patterns 210 have horizontal (i.e., X-direction) phase shifts of π, and vertical (i.e., Y-direction) phase shifts of π/2.

Referring to FIG. 3, the different phases of the patterns 210 (or the phase shifts among the patterns 210) are reflected by their respective trench depths. As discussed above, FIG. 3 is a fragmentary cross-sectional view of the photomask 200 taken from point A to point A′. As is shown in FIG. 3, the patterns 210A-210D correspond to trenches or openings formed in the substrate 205, respectively. The patterns 210A-210D (i.e., the trenches in the substrate 205) have trench depths 230A-230D, respectively. The different phase positions of the patterns 210A-210D dictate that the trench depths 230A-230D be different from one another. For example, the trench 230A may be shallower than the trench depth 230B, which may be shallower than the trench depth 230C, which may be shallower than the trench depth 230D. In other words, trench depths 230A<230B<230C<230D.

It is understood that the trench depths 230A-230D may be exaggerated in FIG. 3 for the sake of providing a clear illustration and that the actual trench depths may be substantially smaller. In addition, the trench depths 230A>230B>230C>230D may hold true in other embodiments. Furthermore, it is understood that in certain embodiments, a pattern may correspond to no trench at all. Rather, the pattern may correspond to a flat surface of the substrate 205. Such pattern may be the pattern that otherwise would have had the smallest trench depth among all the patterns. Also note that portions of the substrate 205 outside the patterns 210A-210D (i.e., the trenches) are covered by a chrome material 240, which is opaque and blocks the transmission of light.

The photomask 200 having the alternating phase shifts is advantageous in enhancing the resolution of a lithography process. In more detail, the spatial frequency is reduced, so that the +1^{st} order beam and the −1^{st} order beam that previously may not have been able to pass through a lens may now be capable of doing so. As discussed above, the amount of phase shift between adjacent patterns 210 in the X-direction is π (180 degree phase shift). Therefore, as long as the illumination is highly coherent—which means the poles on the aperture are sufficiently small—then the line end spacing issue discussed above with reference to FIG. 1 can be avoided. Stated differently, the ample amount of phase shift (180 degrees or π) allows the patterns formed on the wafer to have sufficient resolution in the X direction and to be adequately spaced apart from an adjacent pattern in the X-direction.

Meanwhile, the patterns 210 are also phase shifted in the Y-direction (albeit with a different amount than in the X-direction). Since every pattern 210 has a different phase than its adjacent patterns in the Y-direction, there are no phase-shift conflict issues, which may occur when two adjacent patterns share the same phase. However, as the amount of phase shift between adjacent patterns 210 in the Y-direction is smaller (π/2 or 90 degrees), it alone may or may not enhance the resolution enough to overcome the minimum pitch issue discussed above with reference to FIG. 1.

According to various aspects of the present disclosure, an off-axis illumination (OAI) technique is also implemented to effectively increase the phase shift in the Y-direction, as discussed in more detail below.

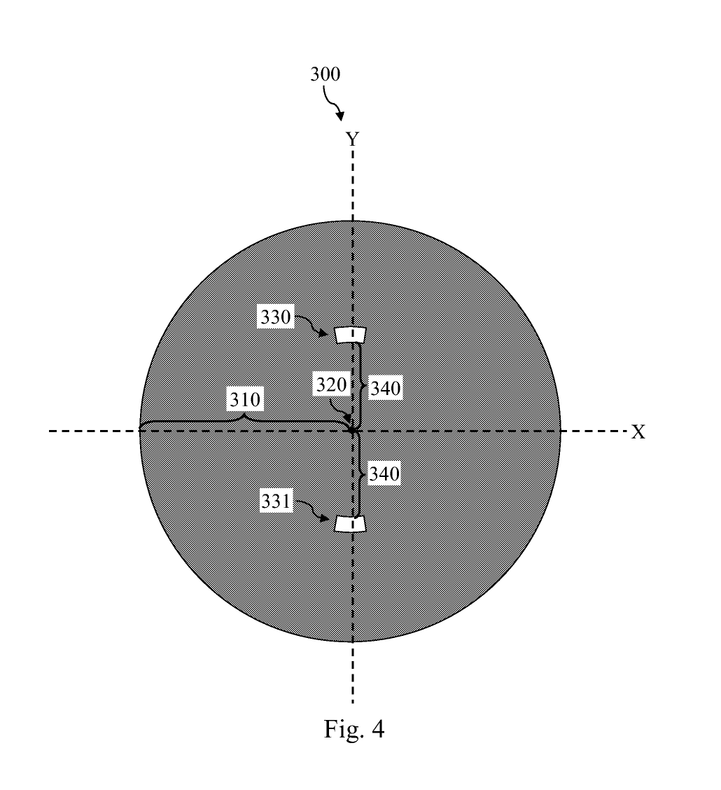

FIG. 4 is a simplified diagrammatic top view of an aperture 300 according to the various aspects of the present disclosure. In the embodiment illustrated, the aperture 300 has an substantially circular shape and therefore has a radius 310. A center 320 of the aperture 300 is defined as an intersection between an X-axis and a Y-axis perpendicular to the X-axis. The X-axis and the Y-axis correspond to the X-direction and the Y-direction discussed above with respect to the photomask 200, respectively. In other words, when the aperture 300 is used in conjunction with the photomask 200 in a lithography process, the X-axis of the aperture 300 is aligned with the X-direction of the photomask 200, and Y-axis of the aperture 300 is aligned with the Y-direction of the photomask 200.

The aperture 300 contains an opaque material. The aperture 300 also includes two poles 330 and 331. The poles 330-331 are openings formed in the opaque material so as to allow light to pass. The poles 330-331 are located on the Y-axis. The poles 330-331 may also take any one of a plurality of suitable shapes, not necessarily the shapes illustrated in FIG. 4. A distance 340 separates the poles 330-331 from the center 320. The distance 340 is less than the radius 310. In other words, the poles 330-331 are not located at or near the outer edges of the aperture 300. In some embodiments, the distance 340 is about ½ of the radius 310. In other embodiments, the distance 340 may be in a range from about 1/16 of the radius 310 to about 15/16 of the radius 310. A size of the poles 330-331 is also sufficiently small to achieve a highly coherent light beam. For example, the size of the poles 330-331 is small enough so that an aperture ratio (σ) is less than 0.8, for example less than about 0.3. The aperture ratio is defined as the ratio of the pupil size of the illumination optics to that of the imaging optics.

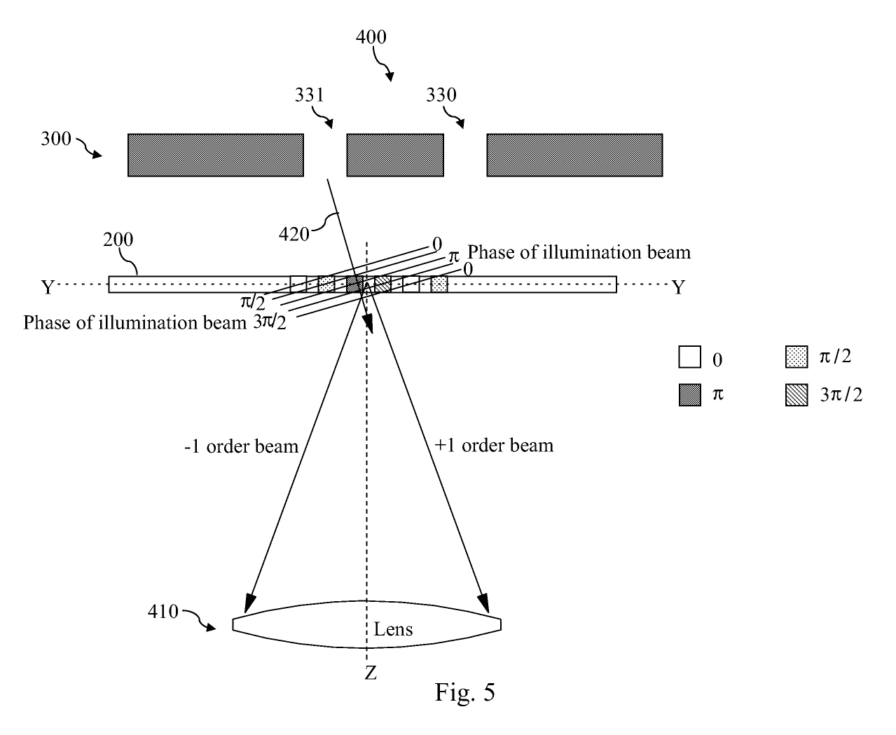

The dislocation of the poles 330-331 from the center of the aperture 300 allows for off-axis illumination. For example, light beams may be projected toward the photomask 200 at an angle, since the light beams will have to pass through the aperture 300 first. This is illustrated in FIG. 5, which shows a simplified diagrammatic cross-section view of an example lithography system 400 according to the various aspects of the present disclosure. The lithography system 400 includes the aperture 300, the photomask 200 located below the aperture 300 in a vertical axis Z, and a lens 410 located below the photomask 200 in the vertical axis Z. The vertical axis Z is orthogonal to the plane defined by the X and Y directions (or X and Y axes) discussed above.

A light beam 420 passes through one of the poles 330-331 and is projected toward the photomask 200. Since the poles 330-331 are “off-axis,” the light beam 420 comes at the photomask 200 at an angle with respect to the axis Z. Thus, the lithography system employs a tilted illumination source. Such “tilted” illumination effectively contributes additional phase shift in the direction in which the poles 330-331 are aligned, which is the Y-direction in the embodiment illustrated.

In some embodiments, the size and location of the poles 330-331 on the aperture 300 are configured in a manner such that the off-axis illumination contributes an additional π/2 or 90 degrees of phase shift in the Y-direction to the patterns on the photomask 200. As discussed above, the phase shift in the Y-direction between adjacent patterns on the photomask 200 is π/2 or 90 degrees. The additional π/2 or 90 degrees of phase shift allows the total amount of phase shift between adjacent patterns in the Y-direction on the photomask 200 to be π or 180 degrees, which is desired. The π or 180 degrees of phase shift reduces the spatial frequency, which allows both the +1^{st} order beam and the −1^{st} order beam to be collected (in the Y-direction) by the lens 410, which enhances resolution in the Y-direction. As such, the combination of the off-axis illumination technique and the alternating phase shift (π/2 or 90 degrees) in the Y-direction results is utilized to resolve the minimum pitch issue discussed above with reference to FIG. 1.

Therefore, the present disclosure involves an off-axis illumination phase shift mask (OPSM or OAIPSM) lithography technique. The OPSM lithography technique combines off-axis illumination and phase shifted masks to effectively resolve both the line end spacing and the minimum pitch issues.

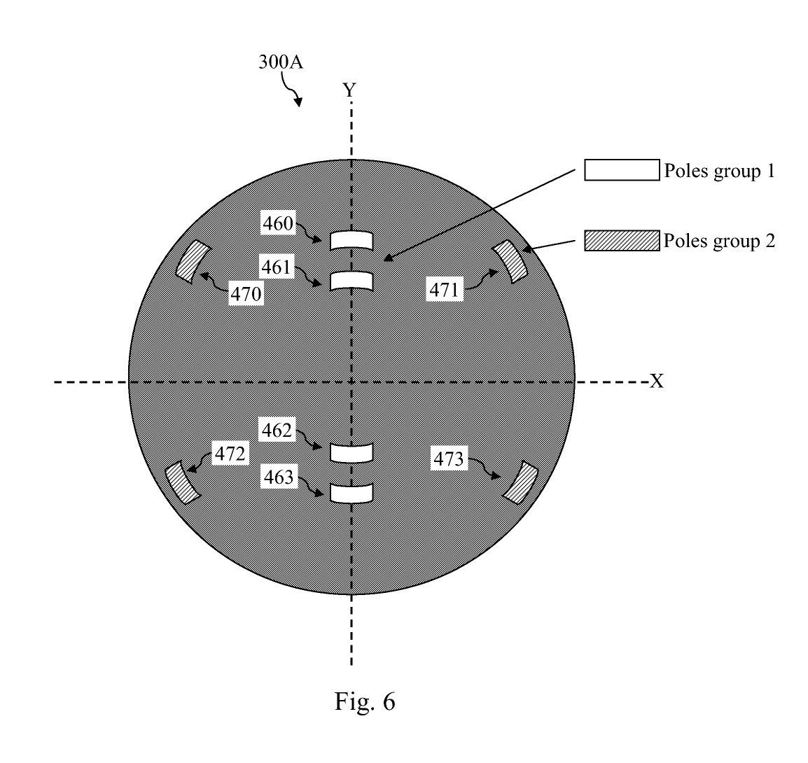

It is understood that the aperture 300 discussed above is merely one of many embodiments of a suitable aperture that can be used in the off-axis illumination lithography system 400. FIG. 6 illustrates a simplified diagrammatic top view of another example embodiment of an aperture 300A according to various aspects of the present disclosure.

In the aperture 300A, two groups of poles are implemented. A first group of poles 460-463 is implemented along the Y-axis. The poles 460-463 are aligned along the Y-axis and are spaced apart from the center of the aperture 300A with distances less than the radius of the aperture 300A. A second group of poles 470-473 is implemented near various corner regions of the aperture 300A. The aperture 300A having multiple poles may improve the performance of the OPSM lithography of the present disclosure. Similarly, other suitable apertures having different number, size, location and arrangements of poles may be used to perform the OPSM lithography discussed above.

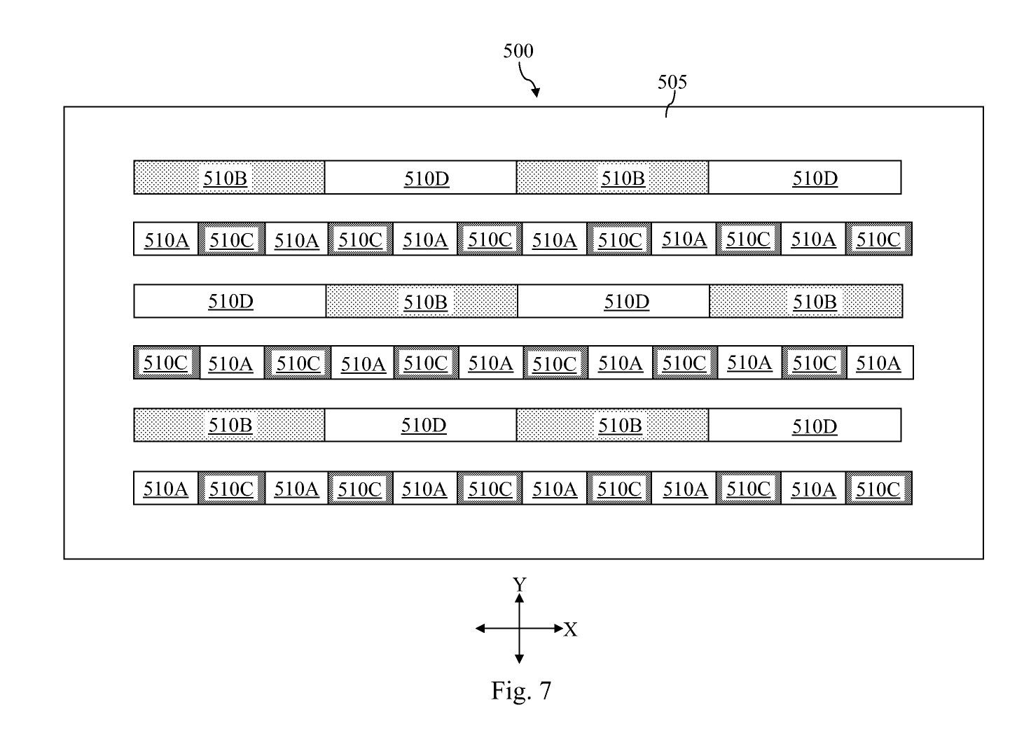

FIG. 7 shows a simplified diagrammatic fragmentary top view of a portion of a photomask 500 according to an alternative embodiment of the present disclosure. The photomask 500 is similar to the photomask 200 of FIG. 2 in many respects. For example, it may include a transparent fused quartz substrate 505 and a plurality of patterns 510 formed in the substrate 505. Unlike the patterns 210 on the photomask 200, however, the patterns 510 on the photomask 500 have vertical (i.e., the Y-direction) phase-shifting (or phase-shifted) edges. In other words, adjacent patterns 510 in the X-direction are bordering or abutting one another. For example, the patterns 510A and 510C are abutted to one another in the X-direction, as are the patterns 510B and 510D. The patterns 510 are still spaced apart from adjacent patterns in the Y-direction. Due to various effects of a lithography process, the patterns formed on a wafer (based on the photomask 500) will still be separated from one another in the X-direction, even though there is no separation between the corresponding photomask patterns in the X-direction.

Each pattern 510 is also phase shifted from adjacent patterns by different amounts in the X and Y directions. In some embodiments, the phase shift between adjacent patterns 510 in the X-direction is π or 180 degrees, whereas the phase shift between adjacent patterns 510 in the Y-direction is π/2 or 90 degrees. Once again, an off-axis illumination method (utilizing the aperture 300 of FIG. 4, for example) discussed above may be used to compensate for the smaller phase shift in the Y-direction, so that the effective phase shift in the Y-direction also approaches π or 180 degrees. Consequently, the lithography process may produce good resolution in both X and Y directions, thereby resolving the minimum pitch issue and the line end spacing issue discussed above.

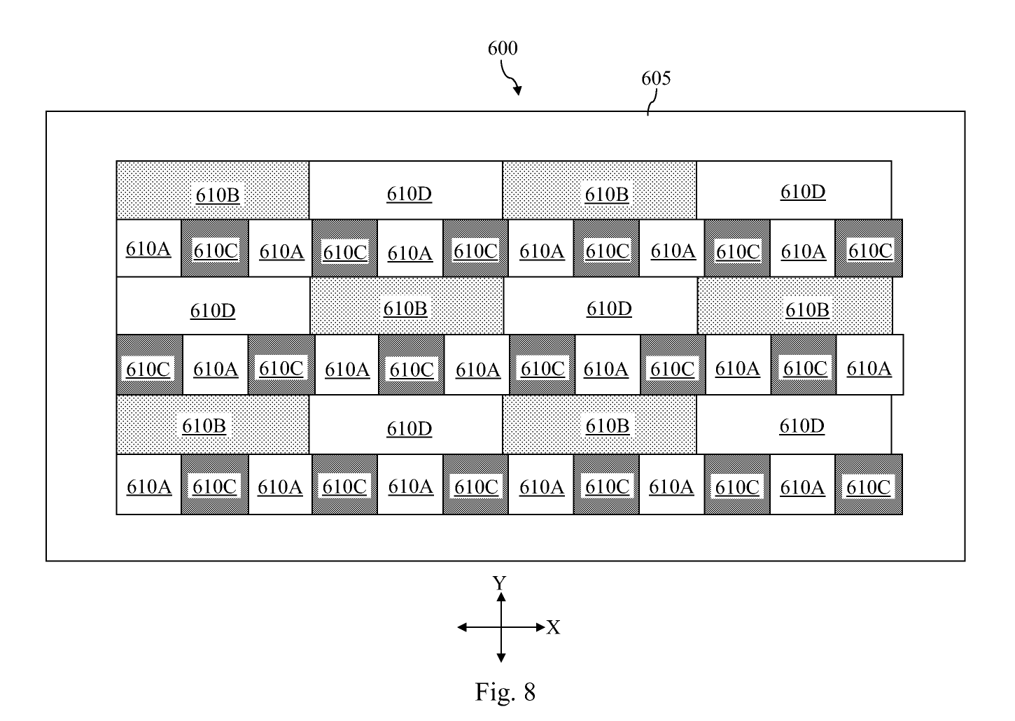

FIG. 8 shows a simplified diagrammatic fragmentary top view of a portion of a photomask 600 according to another alternative embodiment of the present disclosure. The photomask 600 is similar to the photomask 200 of FIG. 2 or the photomask 500 of FIG. 7 in many respects. For example, it includes a transparent fused quartz substrate 605 and a plurality of patterns 610 formed in the substrate 605. Unlike the patterns 210 on the photomask 200, however, the patterns 610 on the photomask 600 have vertical (i.e., the Y-direction) and horizontal (i.e., X-direction) phase-shifting edges. In other words, adjacent patterns 610 are bordering or abutting one another in both the X and Y directions. For example, the patterns 610A and 610C are abutted to one another in the X-direction, as are the patterns 610B and 610D. The patterns 610A and 610B are also abutted to one another in the Y-direction, as are the patterns 610C and 610B or patterns 610C and 610D. Due to various effects of a lithography process, the patterns formed on a wafer (based on the photomask 600) will still be separated from one another in the X and Y directions, even though there is no separation between the patterns in the X and Y directions.

Each patterns 610 is also phase shifted from adjacent patterns by different amounts in the X and Y directions. In some embodiments, the phase shift between adjacent patterns 610 in the X-direction is π or 180 degrees, whereas the phase shift between adjacent patterns 610 in the Y-direction is π/2 or 90 degrees. Once again, an off-axis illumination method (utilizing the aperture 300 of FIG. 4, for example) discussed above may be used to compensate for the smaller phase shift in the Y-direction, so that the effective phase shift in the Y-direction also approaches π or 180 degrees. Consequently, the lithography process may produce good resolution in both X and Y directions, thereby resolving the minimum pitch issue and the line end spacing issue discussed above.

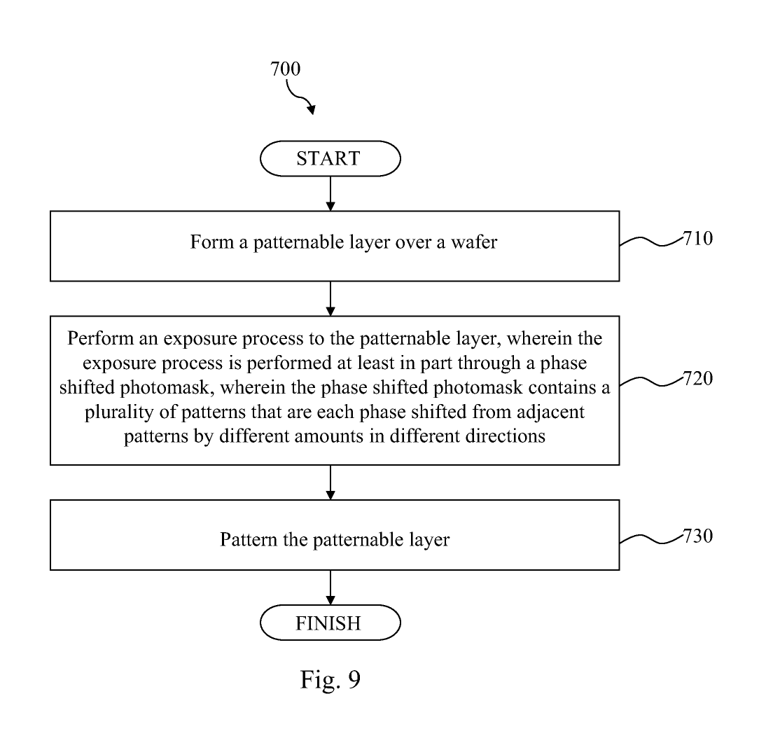

FIG. 9 is a flowchart of a method 700 for performing a lithography process according to various aspects of the present disclosure. The lithography process according to method 700 can be used to fabricate one or more semiconductor devices. The semiconductor device may be a semiconductor Integrated Circuit (IC) chip, system on chip (SoC), or portion thereof, that may include memory circuits, logic circuits, high frequency circuits, image sensors, and various passive and active components such as resistors, capacitors, and inductors, P-channel field effect transistors (pFET), N-channel FET (nFET), metal-oxide semiconductor field effect transistors (MOSFET), or complementary metal-oxide semiconductor (CMOS) transistors, bipolar junction transistors (BJT), laterally diffused MOS (LDMOS) transistors, high power MOS transistors, or other types of transistors.

The method 700 includes a block 710, in which a patternable layer is formed over a wafer. The wafer may include a semiconductor substrate or a portion thereof, for example a silicon substrate that is doped with a P-type dopant such as boron. In other embodiments, the semiconductor substrate may be a silicon substrate doped with an N-type dopant such as arsenic or phosphorous. The substrate may also alternatively be made of some other suitable elementary semiconductor material, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide. Further, in some embodiments, the substrate could include an epitaxial layer (epi layer), may be strained for performance enhancement, and may include a silicon-on-insulator (SOI) structure. In various embodiments, the patternable layer may include a photoresist film.

The method 700 includes a block 720, in which an exposure process is performed to the patternable layer. The exposure process is performed at least in part using a phase shifted photomask. The phase shifted mask contains a plurality of patterns that are each phase shifted from adjacent patterns by different amounts in different directions. For example, the phase shifted mask may be the photomask 200 of FIG. 2, the photomask 500 of FIG. 7, or the photomask 600 of FIG. 8 discussed above. In some embodiments, an amount of phase shift between adjacent patterns of the photomask is approximately an integer multiple of π/2. In various embodiments, a magnitude of an amount of phase shift between adjacent patterns of the photomask is substantially the same in any given direction. In certain embodiments, the patterns of the phase shifted mask are bordering adjacent patterns in at least one direction, for example in either a horizontal direction, a vertical direction, or both. In some embodiments, the exposure process is performed at in part through an off-axis illumination source. The off-axis illumination source may include an aperture having a non-centrally located pole or a plurality of non-centrally located poles. For example, the aperture may be the aperture 300 of FIG. 4 or the aperture 300A of FIG. 6.

The method 700 includes a block 730, in which the patternable layer is patterned. The patterning of the patternable layer may include a post-exposure baking process, a developing process, a rinsing process, etc, so that the patterns of the photomask are transferred to the patternable layer (with different scales).

It is understood that other processes may be performed before, during, or after the blocks 710-730 to complete the lithography process of the method 700. However, for the sake of simplicity, these additional processes are not discussed herein.

The embodiments of the present disclosure offer advantages, it being understood that different embodiments may offer different advantages, and not all the advantages are discussed herein, and that no particular advantage is required for all embodiments.

One of the other advantages of certain embodiments of the present disclosure is that, critical patterns that the phase shifted photomasks discussed above may be used to enhance the resolution of a lithography process. For example, by implementing photomask patterns having phase shifts of about 180 degrees in the X-direction, the line end spacing problem associated with conventional lithography processes can be avoided. Furthermore, the photomask patterns in the Y-direction are also implemented with phase shifts, thereby preventing conflict issues. In addition, the smaller phase shift in the Y-direction is compensated by using an off-axis illumination method (wherein the poles are aligned in the Y-direction), so that the overall phase shift in the Y-direction can still approach 180 degrees. In this manner, the minimum pitch issue associated with conventional lithography processes can also be resolved.

In addition, the embodiments of the present disclosure are compatible with existing process flow and do not increase fabrication costs. Other advantages may exist, but they are not discussed herein for reasons of simplicity.

One of the broader forms of the present disclosure involves a photomask. The photomask includes: a substrate; and a plurality of patterns disposed on the substrate; wherein each pattern is phase shifted from adjacent patterns by different amounts in different directions.

In some embodiments, an amount of phase shift between adjacent patterns is approximately an integer multiple of π/2.

In some embodiments, a magnitude of an amount of phase shift between adjacent patterns is approximately the same in any given direction.

In some embodiments, a magnitude of a first amount of phase shift between adjacent patterns in a first direction is substantially greater than a magnitude of a second amount of phase shift between adjacent patterns in a second direction, the second direction being different from the first direction.

In some embodiments, each pattern is spaced apart from adjacent patterns in both a first direction and a second direction, the first and second directions being perpendicular to one another.

In some embodiments, each pattern is spaced apart from first adjacent patterns in one of a first direction and a second direction but is substantially abutted to second adjacent patterns in another one of the first direction and the second direction, the first and second directions being perpendicular to one another.

In some embodiments, each pattern is abutted to adjacent patterns in both a first direction and a second direction, the first and second directions being perpendicular to one another.

In some embodiments, at least some of the patterns are defined by trenches formed in the substrate; and a phase shift between adjacent patterns is defined as a trench depth difference between adjacent trenches.

Another one of the broader forms of the present disclosure involves a lithography system. The lithography system includes: a photomask that contains a plurality of features formed in a substrate; wherein: each feature has a first phase shift with respect to a first adjacent feature in a first direction; and each feature has a second phase shift with respect to a second adjacent feature in a second direction different from the first direction.

In some embodiments, a magnitude of the first phase shift is substantially equal to π; and a magnitude of the second phase shift is substantially equal to π/2.

In some embodiments, no feature shares a phase shifted edge with its adjacent features.

In some embodiments, each feature shares at least one phase shifted edge with its adjacent features.

In some embodiments, at least some of the features each include an opening formed in the substrate; and a phase shift between adjacent features is defined as a difference between heights of the respective openings of the adjacent features.

In some embodiments, the lithography system further includes an off-axis illumination apparatus disposed over the photomask.

In some embodiments, the off-axis illumination apparatus includes an aperture containing a non-centrally located pole, and wherein a distance from the pole to a center of the aperture is substantially less than a radius of the aperture.

Yet another one of the broader forms of the present disclosure involves a method of performing a lithography process. The method includes: forming a patternable layer over a wafer; performing an exposure process to the patternable layer, wherein the exposure process is performed at least in part through a phase shifted photomask, and wherein the phase shifted photomask contains a plurality of patterns that are each phase shifted from adjacent patterns by different amounts in different directions; and thereafter patterning the patternable layer.

In some embodiments, an amount of phase shift between adjacent patterns of the photomask is approximately an integer multiple of π/2.

In some embodiments, a magnitude of an amount of phase shift between adjacent patterns of the photomask is substantially the same in any given direction.

In some embodiments, the patterns of the phase shifted mask are bordering adjacent patterns in at least one direction.

In some embodiments, the exposure process is performed at in part through an off-axis illumination source.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A photomask, comprising:
a substrate; and
a plurality of patterns disposed on the substrate;
wherein each pattern is phase shifted from adjacent patterns by different amounts in different directions.

2. The photomask of claim 1, wherein an amount of phase shift between adjacent patterns is approximately an integer multiple of π/2.

3. The photomask of claim 1, wherein a magnitude of an amount of phase shift between adjacent patterns is approximately the same in any given direction.

4. The photomask of claim 1, wherein a magnitude of a first amount of phase shift between adjacent patterns in a first direction is substantially greater than a magnitude of a second amount of phase shift between adjacent patterns in a second direction, the second direction being different from the first direction.

5. The photomask of claim 1, wherein each pattern is spaced apart from adjacent patterns in both a first direction and a second direction, the first and second directions being perpendicular to one another.

6. The photomask of claim 1, wherein each pattern is spaced apart from first adjacent patterns in one of a first direction and a second direction but is substantially abutted to second adjacent patterns in another one of the first direction and the second direction, the first and second directions being perpendicular to one another.

7. The photomask of claim 1, wherein each pattern is abutted to adjacent patterns in both a first direction and a second direction, the first and second directions being perpendicular to one another.

8. The photomask of claim 1, wherein:
at least some of the patterns are defined by trenches formed in the substrate; and
a phase shift between adjacent patterns is defined as a trench depth difference between adjacent trenches.

9. A lithography system, comprising:
a photomask that contains a plurality of features formed in a substrate;
wherein:
each feature has a first phase shift with respect to a first adjacent feature in a first direction; and
each feature has a second phase shift with respect to a second adjacent feature in a second direction different from the first direction.

10. The lithography system of claim 9, wherein:
a magnitude of the first phase shift is substantially equal to π; and
a magnitude of the second phase shift is substantially equal to π/2.

11. The lithography system of claim 9, wherein no feature shares a phase shifted edge with its adjacent features.

12. The lithography system of claim 9, wherein each feature shares at least one phase shifted edge with its adjacent features.

13. The lithography system of claim 9, wherein:
at least some of the features each include an opening formed in the substrate; and
a phase shift between adjacent features is defined as a difference between heights of the respective openings of the adjacent features.

14. The lithography system of claim 9, further comprising an off-axis illumination apparatus disposed over the photomask.

15. The lithography system of claim 14, wherein the off-axis illumination apparatus includes an aperture containing a non-centrally located pole, and wherein a distance from the pole to a center of the aperture is substantially less than a radius of the aperture.

16. A method of performing a lithography process, comprising:
forming a patternable layer over a wafer;
performing an exposure process to the patternable layer, wherein the exposure process is performed at least in part through a phase shifted photomask, and wherein the phase shifted photomask contains a plurality of patterns that are each phase shifted from adjacent patterns by different amounts in different directions; and
thereafter patterning the patternable layer.

17. The method of claim 16, wherein an amount of phase shift between adjacent patterns of the photomask is approximately an integer multiple of π/2.

18. The method of claim 16, wherein a magnitude of an amount of phase shift between adjacent patterns of the photomask is substantially the same in any given direction.

19. The method of claim 16, wherein the patterns of the phase shifted mask are bordering adjacent patterns in at least one direction.

20. The method of claim 16, wherein the exposure process is performed at in part through an off-axis illumination source.
